(19) United States
(12) Patent Application Publication
(10) Pub. No.: US 2010/0176725 A1
(43) Pub. Date: Jul. 15, 2010

(54) High-Pressure Discharge Lamp With Improved Ignitability

(75) Inventor: Andreas Kloss, Neubiberg (DE)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRANKTER HAFTUNG, Munchen (DE)

(21) Appl. No.: 12/086,880

(22) PCT Filed: Dec. 6, 2006
(86) PCT No.: PCT/EP2006/069364

§ 371 Date: Jun. 20, 2008

(30) Foreign Application Priority Data
Dec. 23, 2005 (DE) 10 2005 061 831.6

(51) Int. Cl. H01J 61/54; H03K 3/64

(52) U.S. Cl. 315/51; 307/106

(57) ABSTRACT

Disclosed is a high-pressure discharge lamp in which an ignition device that generates high-voltage pulses in the lamp is integrated into the lamp. The ignition device is composed at least of a spiral pulse generator and a charging resistor, said charging resistor being made of an LTCC material.

### TECHNICAL FIELD

The invention is based on a high-pressure discharge lamp in accordance with the preamble of claim 1. Such lamps are in particular high-pressure discharge lamps for general lighting or for photooptical purposes.

### PRIOR ART

The problem associated with the ignition of high-pressure discharge lamps is at present solved by virtue of the fact that the ignition device is integrated in the ballast. One disadvantage with this is the fact that the feed lines need to be designed to be resistant to high voltages.

In the past, repeated attempts have been made to integrate the ignition unit in the lamp. These attempts involve integrating it in the base. Particularly effective ignition which promises high pulses is achieved by means of so-called spiral pulse generators; see U.S. Pat. No. 3,289,015. Quite some time ago such devices were proposed for different high-pressure discharge lamps, such as metal-halide lamps or sodium high-pressure lamps; see U.S. Pat. No. 4,325,004, U.S. Pat. No. 4,353,012, for example. However, they could not be implemented because, for one reason, they are too expensive. Secondly, the advantage of integrating them in the base is insufficient since the problem of supplying the high voltage into the bulb remains. The probability of damage to the lamp, whether it be insulation problems or a rupture in the base, therefore increases considerably. Ignition devices which have been conventional to date generally could not be heated to above 100° C. The voltage generated would then need to be supplied to the lamp, which necessitates lines and lampholders with a corresponding resistance to high voltages, typically approximately 5 kV.

### DESCRIPTION OF THE INVENTION

The object of the present invention is to provide a high-pressure discharge lamp whose ignition response is markedly improved in comparison with previous lamps and with which there is no danger of any damage as a result of the high voltage. This applies in particular to metal-halide lamps, with it being possible for the material of the discharge vessel to either be quartz glass or ceramic.

This object is achieved by the characterizing features of claim 1.

Particularly advantageous configurations are given in the dependent claims.

Furthermore, an object of the present invention is to specify a compact high-voltage pulse generator. This object is achieved by the characterizing features of claim 14.

According to the invention, a high-voltage pulse with at least 1.5 kV, which is required for igniting the lamp, is now generated by means of a special temperature-resistant spiral pulse generator, which is integrated in the immediate vicinity of the discharge vessel in the outer bulb. Not only cold-starting but also hot-restarting is therefore possible.

The spiral pulse generator now used is in particular a so-called LTCC assembly. This material is a special ceramic, which can be made temperature-resistant up to 600° C. Although LTCC has already been used in connection with lamps, see US 2003/0001519 and U.S. Pat. No. 6,853,151, it has been used for entirely different purposes in lamps which are virtually hardly subjected to temperature loading at all, with typical temperatures of below 100° C. The particular value of the high temperature stability of LTCC in connection with the ignition of high-pressure discharge lamps, such as primarily metal-halide lamps with ignition problems, should be recognized.

The spiral pulse generator is an assembly which combines the properties of a capacitor with those of a waveguide for generating ignition pulses with a voltage of at least 1.5 kV. For production purposes, two ceramic “green films” with a metallic conductive paste are printed and then wound in offset fashion to form a spiral and finally pressed isostatically to form a molding. The subsequent co-sintering of metal paste and ceramic film takes place in air in the temperature range of between 800 and 900° C. This processing allows for a use range of the spiral pulse generator with a temperature loading of up to 700° C. As a result, the spiral pulse generator can be accommodated in the direct vicinity of the discharge vessel in the outer bulb, but also in the base or in the immediate vicinity of the lamp.

It is preferable here for it to be accommodated in the outer bulb. This is because this dispenses with the need for a voltage feed line which is resistant to high voltages.

In addition, a spiral pulse generator can be dimensioned such that the high-voltage pulse even allows for hot-restarting of the lamp. The dielectric made from ceramic is characterized by an extremely high dielectric constant ε of ε>10, with it being possible for an ε of typically 70, up to ε=100 to be achieved depending on the material and construction. This allows for a very high capacity of the spiral pulse generator and allows for a comparatively large temporal width of the pulses generated. As a result, a very compact design of the spiral pulse generator is possible, with the result that it can be integrated in conventional outer bulbs of high-pressure discharge lamps.

In addition, on the basis of this high-voltage pulse generator an ignition unit can be specified which furthermore comprises at least one charging resistor and a switch. The switch may be a spark gap or else a diac using SiC technology. In this case, the ignition unit is extremely compact, since after all the charging resistor is integrated in the high-voltage pulse generator.

As a result, a very compact design of the spiral pulse generator is possible, with the result that it can be integrated in conventional outer bulbs of high-pressure discharge lamps. A particularly compact design can be achieved because the charging resistor is not a separate assembly which is merely connected to the spiral pulse generator. Since the charging resistor nevertheless needs to satisfy the same conditions as the spiral pulse generator as regards its temperature resistance, it is recommended to produce it from LTCC material in a similar way to the spiral pulse generator.

Preferably, the charging resistor can in this case be integrated on the inner edge in the spiral pulse generator, with the result that the two together are configured as an LTCC ceramic assembly. This assembly is resistant up to a temperature of approximately 600° C. As a result, a contact point is avoided which would otherwise likewise need to be designed to be temperature-resistant. Apart from the high-voltage switch, usually a spark gap or diac, no other assemblies are therefore required.

Any conventional glass can be used as the material of the outer bulb, i.e. in particular hard glass, vycor or quartz glass. The choice of filling is also not subject to any particular restriction.

### BRIEF DESCRIPTION OF THE DRAWINGS

The invention will be explained in more detail below with reference to a plurality of exemplary embodiments. In the figures:

FIG. 1 shows the basic design of a spiral pulse generator;

FIG. 2 shows characteristics of an LTCC spiral pulse generator;

FIG. 3 shows the basic design of a sodium high-pressure lamp with a spiral pulse generator in the outer bulb;

FIG. 4 shows the basic design of a metal-halide lamp with a spiral pulse generator in the outer bulb;

FIG. 5 shows a metal-halide lamp with a spiral pulse generator in the outer bulb;

FIG. 6 shows a metal-halide lamp with a spiral pulse generator in the base.

### PREFERRED EMBODIMENT OF THE INVENTION

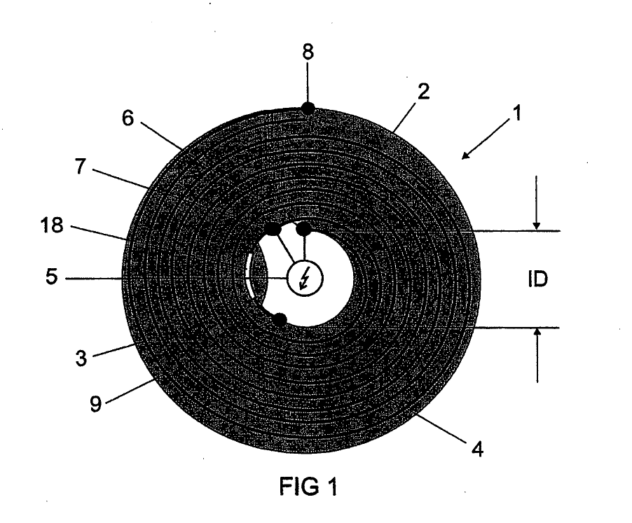

FIG. 1 shows the design of a spiral pulse generator 1 in a plan view. It comprises a ceramic cylinder 2, into which two different metallic conductors 3 and 4 are wound in spiral fashion in the form of a foil strip. The cylinder 2 is hollow on the inside and has a given inner diameter ID. The two inner contacts 6 and 7 of the two conductors 3 and 4 are connected to one another via a spark gap 5.

Only the outer one of the two conductors has a further contact 8 on the outer edge of the cylinder. The other conductor ends open. The two conductors thereby together form a waveguide in a dielectric medium, the ceramic. A line section consisting of a different material adjoins the inner contact 7 of the one conductor and acts as a charging resistor 18.

The spiral pulse generator is either wound from two ceramic films coated with metal paste or constructed from two metal foils and two ceramic films. An important characteristic in this case is the number n of turns, which should preferably be of the order of magnitude of from 5 to 100. This coil arrangement is then laminated and subsequently sintered, which results in an LTCC assembly. The spiral pulse generators created in such a way with a capacitor property are then connected to a spark gap.

The spark gap can be located at the inner or the outer terminals or else within the winding of the generator. A spark gap which is based on SiC and is very thermally stable can preferably be used as the high-voltage switch, which initiates the pulse. For example, the switching element MESFET by Cree can be used. This is suitable for temperatures of above 350° C.

In a specific exemplary embodiment, a ceramic material where ε=60 to 70 is used. The dielectric used here is preferably a ceramic film, in particular a ceramic strip such as Heratape CT 707 or preferably CT 765 or else a mixture of the two, each by Heraeus. It has a thickness of the green film of typically from 50 to 150 μm. The conductor used is in particular Ag conductive paste such as “Cofirable Silver”, likewise by Heraeus. A specific example is CT 700 from Heraeus. Good results are also achieved with the metal paste 6142 by DuPont. These parts can be laminated effectively and then burnt out and sintered together (“co-firing”).

The inner diameter ID of the spiral pulse generator is 10 mm. The width of the individual strips is likewise 10 mm. The film thickness is 50 μm and also the thickness of the two conductors is in each case 50 μm. The charging voltage is 300 V. Under these conditions, the spiral pulse generator achieves an optimum for its properties with a turns number of n=20 to 70.

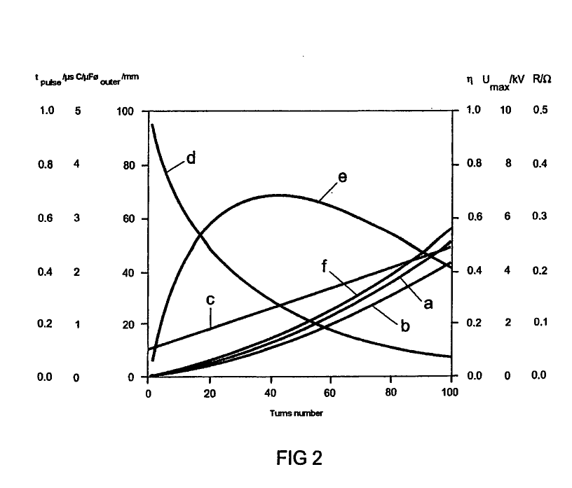

FIG. 2 illustrates the associated full width at half maximum of the high-voltage pulse in μs (curve a), the total capacitance of the assembly in μF (curve b), the resultant outer diameter in mm (curve c), and the efficiency (curve d), the maximum pulse voltage (curve e) in kV and the conductor resistance in Ω (curve f).

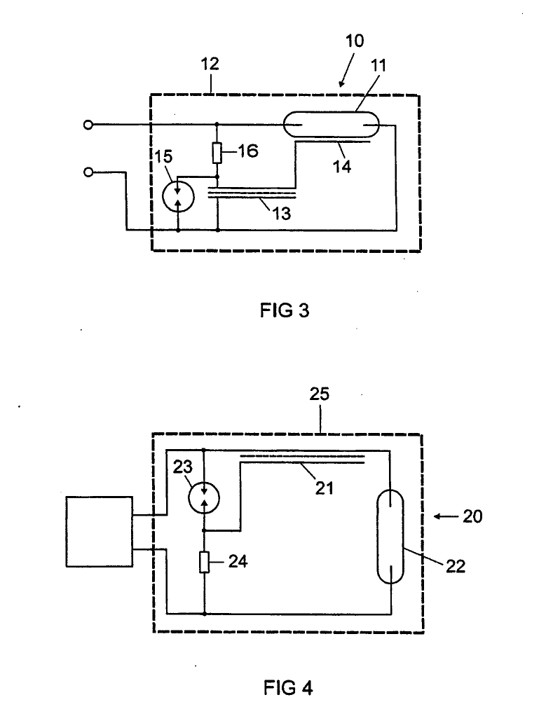

FIG. 3 shows the basic design of a sodium high-pressure lamp 10 with a ceramic discharge vessel 11 and an outer bulb 12 with a spiral pulse generator 13 integrated therein, an ignition electrode 14 being fitted on the outside on the ceramic discharge vessel 11. The spiral pulse generator 13 with the integrated charging resistor is accommodated together with the spark gap 15 in the outer bulb.

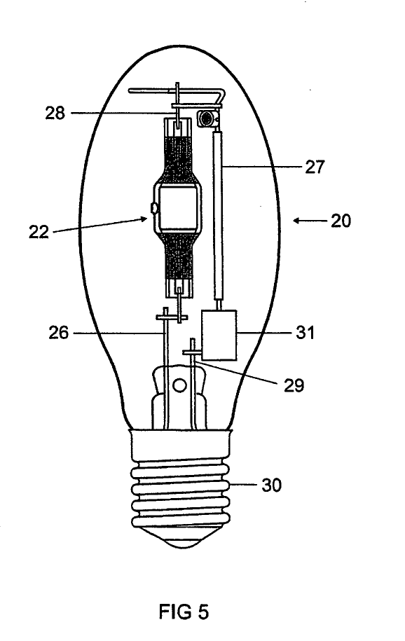

FIG. 4 shows the basic design of a metal-halide lamp 20 with an integrated spiral pulse generator 21, with no ignition electrode being fitted on the outside on the discharge vessel 22, which can be manufactured from quartz glass or ceramic. The spiral pulse generator 21 with the integrated charging resistor is accommodated together with the spark gap 23 in the outer bulb 25.

FIG. 5 shows a metal-halide lamp 20 with a discharge vessel 22, which is held by two feed lines 26, 27 in an outer bulb. The first feed line 26 is a wire with a short section bent back. The second feed line 27 is substantially a bar, which leads to the leadthrough 28 remote from the base. An ignition unit 31, which contains the spiral pulse generator, the spark gap and the charging resistor, is arranged between the feed line 29 out of the base 30 and the bar 27, as indicated in FIG. 4.

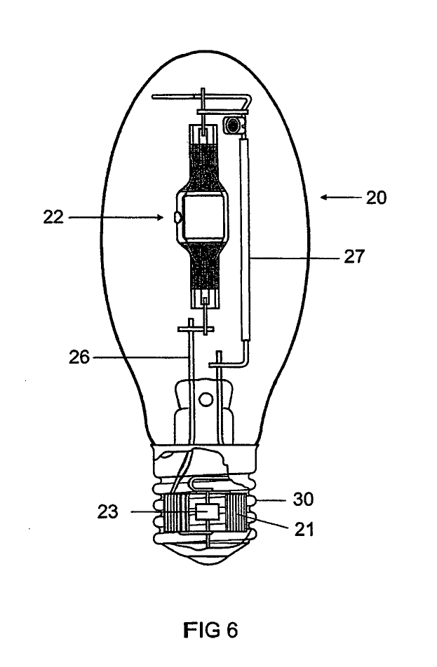

FIG. 6 shows a metal-halide lamp 20 similar to that in FIG. 5 with a discharge vessel 22, which is held by two feed lines 26, 27 in an outer bulb 25. The first feed line 26 is a wire with a short section bent back. The second feed line 27 is substantially a bar, which leads to the leadthrough 28 remote from the base. In this case, the ignition unit is arranged in the base 30, to be precise both the spiral pulse generator 21 with the integrated charging resistor and the spark gap 23.

This technology can also be used for lamps without electrodes, it being possible for the spiral pulse generator to act as ignition aid.

Further applications of this compact high-voltage pulse generator involve the ignition of other devices. The application is primarily advantageous in so-called magic spheres, in the generation of X-ray pulses and the generation of electron beam pulses. A use in motor vehicles as a replacement for the conventional ignition coils is also possible.

In this case, turns numbers of n up to 500 are used so that the output voltage of up to the order of magnitude of 100 kV is achieved. This is because the output voltage U_{A} is given, as a function of the charge voltage U_{L}, by U_{A}=2×n×U_{L}×η, with the efficiency η being given by η=(AD−ID)/AD.

The invention is associated with particular advantages in interaction with high-pressure discharge lamps for automobile headlamps which are filled with xenon under a high pressure of preferably at least 3 bar and metal halides. These are particularly difficult to ignite since the ignition voltage is more than 10 kV as a result of the high xenon pressure. At present attempts are being made to accommodate the components of the ignition unit in the base. A spiral pulse generator with an integrated charging resistor can be accommodated either in the base of the motor vehicle lamp or in an outer bulb of the lamp.

The invention involves very particular advantages in interaction with high-pressure discharge lamps which do not contain any mercury. Such lamps are particularly desirable for environmental protection reasons. They contain a suitable metal halide filling and in particular a noble gas such as xenon under high pressure. As a result of the lack of mercury, the ignition voltage is particularly high. It is more than 20 kV. At present attempts are being made to accommodate the components of the ignition unit in the base. A spiral pulse generator with an integrated charging resistor can be accommodated either in the base of the mercury-free lamp or in an outer bulb of the lamp.

1. A high-pressure discharge lamp with a discharge vessel, which is in particular accommodated in an outer bulb and is held there by a frame, an ignition apparatus being integrated in the lamp which produces high-voltage pulses in the lamp, characterized in that the ignition apparatus at least comprises a spiral pulse generator and a charging resistor, the charging resistor being manufactured from an LTCC material.

2. The high-pressure discharge lamp as claimed in claim 1, characterized in that the charging resistor is accommodated in the outer bulb.

3. The high-pressure discharge lamp as claimed in claim 1, characterized in that the ignition apparatus is part of the frame.

4. The high-pressure discharge lamp as claimed in claim 1, characterized in that the spiral pulse generator is produced from a temperature-resistant material, in particular from LTCC.

5. The high-pressure discharge lamp as claimed in claim 4, characterized in that the spiral pulse generator and the charging resistor are constructed together as an integrated LTCC assembly.

6. The high-pressure discharge lamp as claimed in claim 6, characterized in that the charging resistor on the LTCC assembly is integrated in the innermost ceramic insulating layer.

7. The high-pressure discharge lamp as claimed in claim 7, characterized in that the charging resistor is electrically connected to that conductor which remains open at the outer end of the spiral pulse generator.

8. The high-pressure discharge lamp as claimed in claim 1, characterized in that the spiral pulse generator is constructed from a plurality of layers, the number n of layers being at least n=5.

9. The high-pressure discharge lamp as claimed in claim 7, characterized in that the number n of layers is at most n=500.

10. The high-pressure discharge lamp as claimed in claim 1, characterized in that the spiral pulse generator has an approximately cylindrical design, with an inner diameter ID of at least 10 mm.

11. The high-pressure discharge lamp as claimed in claim 1, characterized in that the dielectric constant ε of the spiral pulse generator is at least ε=10.

12. The high-pressure discharge lamp with a discharge vessel and with an associated ignition apparatus, the ignition apparatus generating high-voltage pulses and containing a spiral pulse generator, characterized in that the spiral pulse generator is manufactured from an LTCC material, the charging resistor being integrated in the spiral pulse generator.

13. The high-pressure discharge lamp as claimed in claim 12, characterized in that the spiral pulse generator is accommodated in the lamp, preferably in the base or in an outer bulb of the lamp.

14. A compact high-voltage pulse generator based on a spiral pulse generator, characterized in that the spiral pulse generator is in the form of an LTCC assembly comprising ceramic films and metallic conductive paste, a charging resistor being integrated in the spiral pulse generator, in particular by a resistive paste being used for this.

15. The high-voltage pulse generator as claimed in claim 14, characterized in that the spiral comprises at least 5 turns.

16. An ignition unit based on a high-voltage pulse generator as claimed in claim 14, characterized in that it furthermore comprises at least one switch.
